(19) United States
(12) Patent Application Publication
(10) Pub. No.: US 2026/0204670 A1
(43) Pub. Date: Jul. 16, 2026

(54) METHOD FOR DETECTING ABNORMALITY IN STORAGE BATTERY

(71) Applicant: TOYOTA JIDOSHA KABUSHIKI KAISHA, Toyota-shi (JP)

(72) Inventor: Koichiro Isobe, Toyota-shi (JP)

(73) Assignee: TOYOTA JIDOSHA KABUSHIKI KAISHA, Toyota-shi (JP)

(21) Appl. No.: 19/377,064

(22) Filed: Nov. 3, 2025

(30) Foreign Application Priority Data
Jan. 15, 2025 (JP) 2025-005587

(51) Int. Cl. H01M 10/48; G01B 21/32

(52) U.S. Cl. CPC H01M 10/482; G01B 21/32

(57) ABSTRACT

According to one embodiment of the present disclosure, a method for detecting an abnormality in a storage battery includes: calculating, based on process data obtained during a manufacturing process, an initial restraining deformation amount of a target prismatic cell in a stack of prismatic cells; calculating, based on the initial restraining deformation amount and usage history data, a deformation amount of the bottom surface of the case of the target prismatic cell; and outputting a first alert in response to the deformation amount of the bottom surface of the case exceeding a predetermined first threshold.

### CROSS-REFERENCE TO RELATED APPLICATION

This application claims priority to Japanese Patent Application No. 2025-005587 filed on January 15, 2025. The disclosure of the above-identified application, including the specification, drawings, and claims, is incorporated by reference herein in its entirety.

### BACKGROUND

### 1 Technical Field

The present disclosure relates to methods for detecting an abnormality in a storage battery, particularly in a storage battery in which a stack of a plurality of prismatic cells is bonded to a base plate by a thermally conductive material.

### 2 Description of Related Art

Japanese Unexamined Patent Application Publication No. 2016-027538 (JP 2016-027538 A) discloses a technique for detecting changes in internal pressure or electrode swelling of a sealed secondary battery using a monitoring sensor.

### SUMMARY

In a storage battery in which a stack of a plurality of prismatic cells is bonded to a base plate by a thermally conductive material, one type of abnormality to be detected is deformation of the bottom surfaces of the cell cases due to expansion of the cells. Such deformation of the bottom surfaces may lead to detachment of the thermally conductive material from the bottom surfaces. If the deformation further progresses, it may result in a short circuit due to contact between the case and the electrode assembly inside the case. One possible method for detecting such an abnormality is to use a monitoring sensor, as in the related art described above. However, using a monitoring sensor to detect deformation of the bottom surfaces of the cases can lead to an increase in the overall size and cost of the energy storage device.

A method according to one embodiment of the present disclosure is a method for detecting an abnormality in a storage battery including a stack of a plurality of prismatic cells bonded to a base plate by a thermally conductive material. The method includes: calculating, based on process data obtained during a manufacturing process, an initial restraining deformation amount of a target prismatic cell in the stack; calculating, based on the initial restraining deformation amount and usage history data, a deformation amount of a bottom surface of a case of the target prismatic cell; and outputting a first alert in response to the deformation amount exceeding a predetermined first threshold.

According to the present disclosure, the deformation amount of the bottom surface of the case of the prismatic cell can be obtained through computation based on data. This allows an abnormality caused by deformation of the bottom surface of the case of the prismatic cell to be detected without using a sensor that physically detects deformation.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1A illustrates the configuration of a storage battery including a stack of a plurality of prismatic cells, and an abnormality caused by deformation of the prismatic cells;

FIG. 1B illustrates the configuration of a storage battery including a stack of a plurality of prismatic cells, and an abnormality caused by deformation of the prismatic cells;

FIG. 1C illustrates the configuration of a storage battery including a stack of a plurality of prismatic cells, and an abnormality caused by deformation of the prismatic cells;

FIG. 1D illustrates the configuration of a storage battery including a stack of a plurality of prismatic cells, and an abnormality caused by deformation of the prismatic cells;

FIG. 1E illustrates the configuration of a storage battery including a stack of a plurality of prismatic cells, and an abnormality caused by deformation of the prismatic cells;

FIG. 2 is a graph illustrating an example of changes in the deformation amount of the bottom surfaces of the cases of the prismatic cells due to repeated charging and discharging;

FIG. 3 is a flowchart illustrating a method for detecting an abnormality caused by deformation of the bottom surfaces of the cases of the prismatic cells;

FIG. 4 is a graph illustrating an example of changes in the deformation amount of the prismatic cells in the stacking direction due to repeated charging and discharging; and

FIG. 5 is a flowchart illustrating a method for detecting an abnormality caused by deformation of the prismatic cells in the stacking direction.

### DETAILED DESCRIPTION OF EMBODIMENTS

### 1 Overview of Abnormalities in Storage Battery

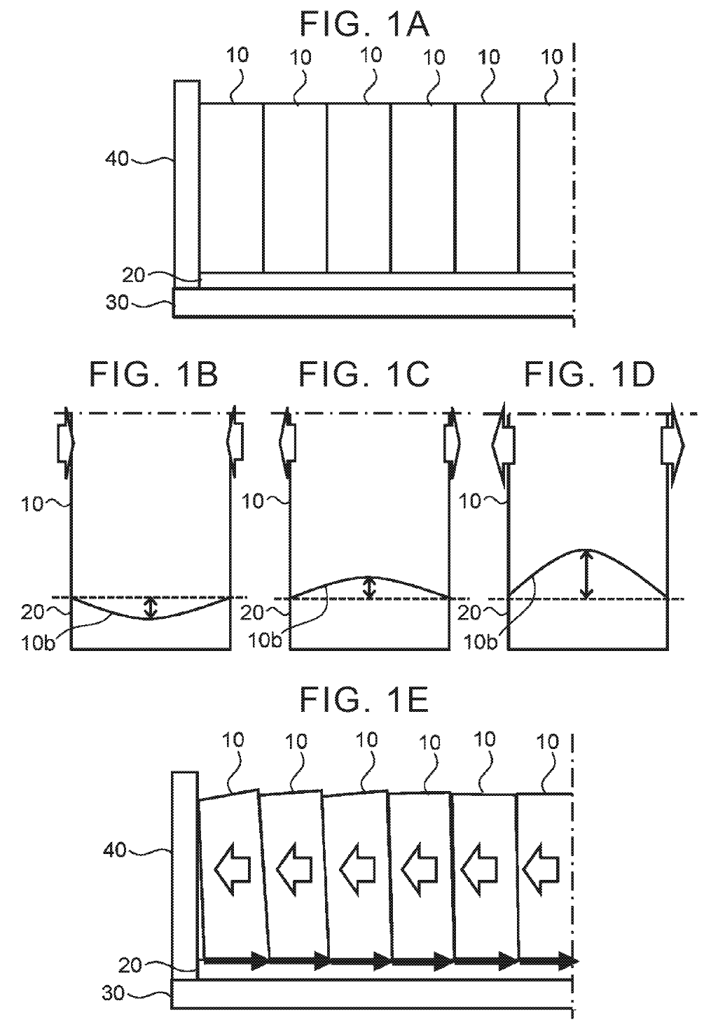

FIGS. 1A, 1B, 1C, 1D, and 1E illustrate the configuration of a storage battery including a stack of a plurality of prismatic cells, and an abnormality caused by deformation of the prismatic cells. One known example of a storage battery used in a battery electric vehicle is a storage battery pack in which a plurality of prismatic cells is stacked to form a module, and a plurality of such modules are assembled into a pack.

As shown in FIG. 1A, in the modularization process, a stack of a plurality of prismatic cells 10 is fitted between end plates 40 in a constrained and compressed state in the stacking direction. The stack of prismatic cells 10 is then bonded to a base plate 30 by a thermally conductive material 20, more specifically, by an adhesive having thermally conductive properties. The base plate 30 may have a cooling function.

Even after the stack is fitted between the end plates 40, the restraining load remains, and each prismatic cell 10 is deformed by the restraining load. The restraining load remaining in the prismatic cells 10 at the time of shipment of the storage battery pack, that is, the restraining load in the initial state, is herein referred to as "initial restraining load." Deformation caused by the initial restraining load includes deformation of the prismatic cells 10 in the height direction. FIG. 1B shows the cross-sectional shape of a prismatic cell 10 in its initial state. In the initial state, a bottom surface 10b of the case of the prismatic cell 10 is deformed into a downward convex shape due to the initial restraining load.

The prismatic cell 10 gradually expands in the stacking direction as a result of charge and discharge. For example, as shown in FIG. 1C, expansion of the prismatic cell 10 begins from the initial charge, and as the prismatic cell 10 expands in the stacking direction, the bottom surface 10b of the case is deformed into an upward concave shape. As shown in FIG. 1D, as degradation progresses due to repeated charging and discharging, the expansion of the prismatic cell 10 in the stacking direction during charging increases.

Accordingly, the deformation amount of the bottom surface 10b of the case in the upward concave direction, that is, in the inward direction, also increases. As the bottom surface 10b of the case is deformed in the upward concave direction, tensile-direction stress acts between the bottom surface 10b and the thermally conductive material 20.

This tensile-direction stress acting between the bottom surface 10b and the thermally conductive material 20 may cause the thermally conductive material 20 to detach from the bottom surface 10b of the case. If the deformation of the bottom surface 10b of the case further progresses, there is a possibility that a short circuit may occur due to contact between the case and the electrode assembly inside the case. That is, the deformation of the bottom surface 10b of the case caused by repeated charging and discharging may lead to an abnormality in which the thermally conductive material 20 detaches from the bottom surface 10b, and furthermore, may also lead to another abnormality in which a short circuit occurs due to contact between the case and the electrode assembly inside the case.

Deformation caused by the initial restraining load includes deformation of the prismatic cells 10 in the stacking direction. The deformation amount of the prismatic cells 10 in the stacking direction increases as the prismatic cells 10 expand with repeated charging and discharging. Due to this expansion, as indicated by the white arrow lines in FIG. 1E, the stacked prismatic cells 10 are sequentially pushed from the center toward the end plates 40. Since the bottom surfaces 10b of the cases are bonded to the base plate 30 by the thermally conductive material 20, shear-direction stress, as indicated by the black arrow lines, acts between the bottom surfaces 10b and the thermally conductive material 20.

This shear-direction stress acting between the bottom surfaces 10b and the thermally conductive material 20 may cause the thermally conductive material 20 to detach from the bottom surfaces 10b of the cases. That is, deformation of the prismatic cells 10 in the stacking direction caused by repeated charging and discharging may lead to an abnormality in which the thermally conductive material 20 detaches from the bottom surfaces 10b of the cases.

### 2 Method for Detecting Abnormality Caused by Deformation of Bottom Surfaces of Cases of Prismatic Cells

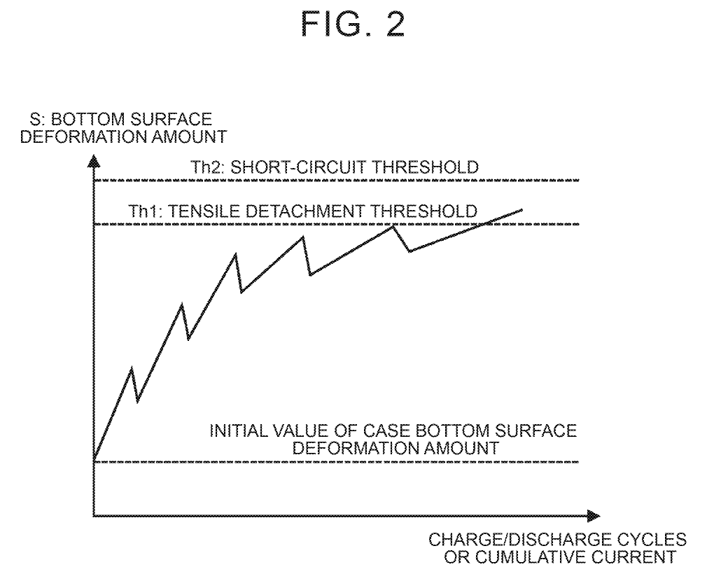

Deformation of the bottom surfaces 10b of the cases of the prismatic cells 10 increases with repeated charging and discharging. FIG. 2 is a graph illustrating an example of changes in the deformation amount of the bottom surfaces 10b due to repeated charging and discharging. As shown in FIG. 2, the deformation amount S of the bottom surfaces 10b of the cases (hereinafter referred to as "bottom surface deformation amount S") increases and decreases repeatedly as charging and discharging are repeated, while gradually increasing overall. When the bottom surface deformation amount S exceeds a predetermined first threshold Th1, detachment of the thermally conductive material 20 may occur due to tensile-direction stress. Furthermore, when the bottom surface deformation amount S exceeds a predetermined second threshold Th2 that is greater than the first threshold Th1, a short circuit may occur due to contact between the case and the electrode assembly inside the case. Hereinafter, the first threshold Th1 is referred to as "tensile detachment threshold," and the second threshold Th2 is referred to as "short-circuit threshold." The specific values of the tensile detachment threshold and the short-circuit threshold are determined according to the specifications of the storage battery, and can be identified, for example, through testing or simulation.

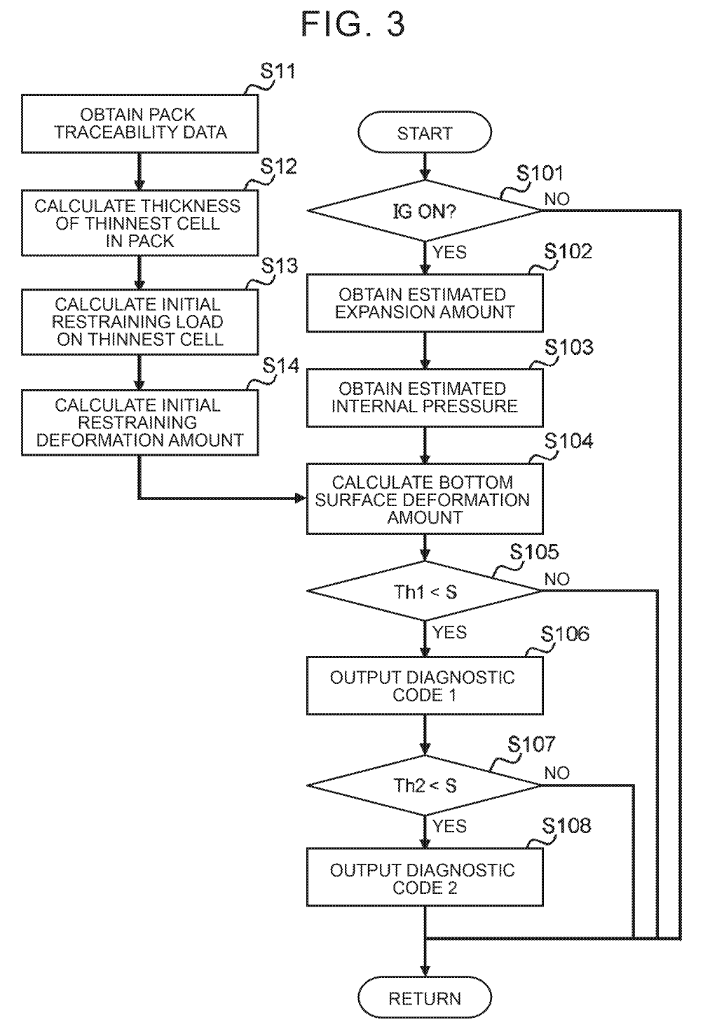

FIG. 3 is a flowchart illustrating a method for detecting an abnormality caused by deformation of the bottom surfaces 10b of the cases of the prismatic cells 10. One feature of the method illustrated in this flowchart is that the bottom surface deformation amount is obtained through computation, rather than physically detecting the deformation of the bottom surfaces 10b of the cases of the prismatic cells 10 using a sensor. This method can be executed by a computer.

The computation of the bottom surface deformation amount is performed for a target prismatic cell among the prismatic cells 10 constituting the storage battery pack. In the present embodiment, the target prismatic cell is the thinnest prismatic cell in the storage battery pack. The thinnest prismatic cell is the cell in which deformation of the bottom surface 10b of the case becomes the largest when expansion in the stacking direction occurs, that is, the cell in which detachment of the thermally conductive material 20 or a short circuit is most likely to occur. However, the target prismatic cell may be selected as desired. The target prismatic cell may be a single prismatic cell, two or more prismatic cells, or all of the prismatic cells.

In the flowchart shown in FIG. 3, the processes of steps S11 to S14 are preparatory processes that are executed once, for example, prior to shipment of the storage battery pack or prior to shipment of a battery electric vehicle (BEV) in which the storage battery pack is installed. In step S11, traceability data of the storage battery pack to be monitored for abnormality is obtained. The traceability data includes process data obtained during the manufacturing process of the storage battery pack. In step S12, the thinnest prismatic cell is identified based on the traceability data, and the thickness of the thinnest prismatic cell is calculated. In step S13, the initial restraining load on the thinnest prismatic cell is calculated based on the thickness of the thinnest prismatic cell and the traceability data. In step S14, the initial restraining deformation amount of the thinnest prismatic cell, specifically, the initial value of the bottom surface deformation amount, is calculated based on the thickness and the initial restraining load of the thinnest prismatic cell. The initial value of the bottom surface deformation amount computed in step S14 is stored in the memory of the computer.

In the flowchart shown in FIG. 3, the processes of steps S101 to S108 are executed repeatedly each time the BEV is operated after shipment of the BEV in which the storage battery pack is installed. In step S101, it is determined whether the ignition (IG) has been turned on. While the IG is off, the subsequent processes are skipped. When the IG is turned on, the processes from step S102 onward are executed.

In step S102, the estimated expansion amount of the thinnest prismatic cell is obtained. There is no limitation on the method used to estimate the expansion amount. Assuming that the expansion amounts of all the prismatic cells are approximately equal, the average estimated expansion amount of the prismatic cells in the entire storage battery pack may be used as the estimated expansion amount of the thinnest prismatic cell. For example, a known method such as the one described in Japanese Unexamined Patent Application Publication No. 2023-11289 (JP 2023-11289 A) may be used for the estimation.

In step S103, the estimated internal pressure of the thinnest prismatic cell is obtained. There is no limitation on the method used to estimate the internal pressure. Assuming that the internal pressures of all the prismatic cells are approximately equal, the average estimated internal pressure of the prismatic cells in the entire storage battery pack may be used as the estimated internal pressure of the thinnest prismatic cell. For example, a known method such as the one described in Japanese Unexamined Patent Application Publication No. 2019-118216 (JP 2019-118216 A) may be used for the estimation. The processes of steps S102 and S103 may be executed in reverse order, or may be executed simultaneously.

In step S104, the bottom surface deformation amount of the thinnest prismatic cell is calculated based on the initial value of the bottom surface deformation amount calculated in step S14 and stored in the memory, the estimated expansion amount obtained in step S102, and the estimated internal pressure obtained in step S103. The estimated expansion amount and the estimated internal pressure are used to compute the amount of change in the bottom surface deformation amount from the initial value. The relationship between the bottom surface deformation amount and each of the expansion amount and the internal pressure is defined by a physical model or a map.

In step S105, the bottom surface deformation amount S obtained in step S104 is compared with the tensile detachment threshold Th1 to determine whether the bottom surface deformation amount S has increased to a level at which tensile detachment of the thermally conductive material 20 may occur. When the bottom surface deformation amount S is less than or equal to the tensile detachment threshold Th1, the subsequent processes are skipped. When the bottom surface deformation amount S is greater than the tensile detachment threshold Th1, diagnostic code 1 is output in step S106. Diagnostic code 1 is an alert indicating a potential tensile detachment of the thermally conductive material 20.

When diagnostic code 1 is output, the determination in step S107 is performed. In step S107, the bottom surface deformation amount S obtained in step S104 is compared with the short-circuit threshold Th2 to determine whether the bottom surface deformation amount S has increased to a level at which a short circuit may occur. When the bottom surface deformation amount S is less than or equal to the short-circuit threshold Th2, the subsequent processes are skipped. When the bottom surface deformation amount S is greater than the short-circuit threshold Th2, diagnostic code 2 is output in step S108. Diagnostic code 2 is an alert indicating a potential short circuit. The alert corresponding to diagnostic code 1 is herein referred to as "first alert," and the alert corresponding to diagnostic code 2 is referred to as "second alert."

### 3 Method for Detecting Abnormality Caused by Deformation of Prismatic Cells in Stacking Direction

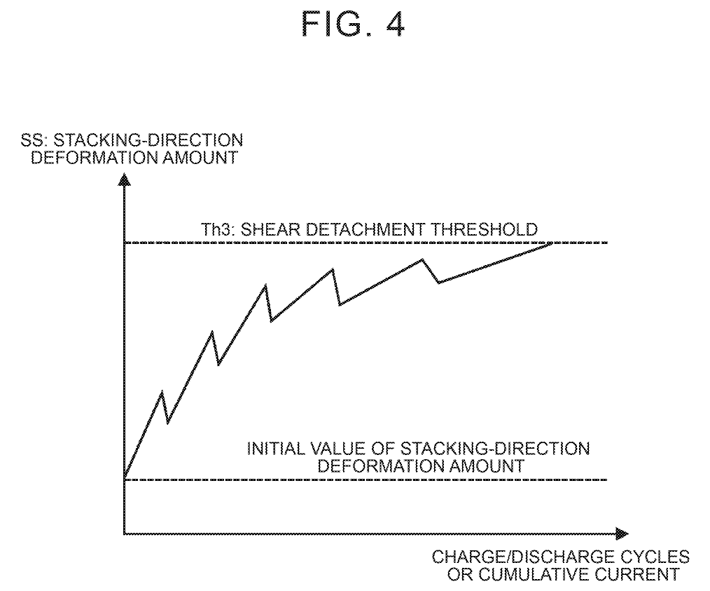

Deformation of the prismatic cells 10 in the stacking direction increases with repeated charging and discharging. FIG. 4 is a graph illustrating an example of changes in the deformation amount in the stacking direction (hereinafter referred to as "stacking-direction deformation amount SS") due to repeated charging and discharging. As shown in FIG. 4, the stacking-direction deformation amount SS increases and decreases repeatedly as charging and discharging are repeated, while gradually increasing overall. When the stacking-direction deformation amount SS exceeds a predetermined third threshold Th3, detachment of the thermally conductive material 20 may occur due to shear-direction stress. The third threshold Th3 is hereinafter referred to as "shear detachment threshold." The specific value of the shear detachment threshold is determined according to the specifications of the storage battery, and can be identified, for example, through testing or simulation.

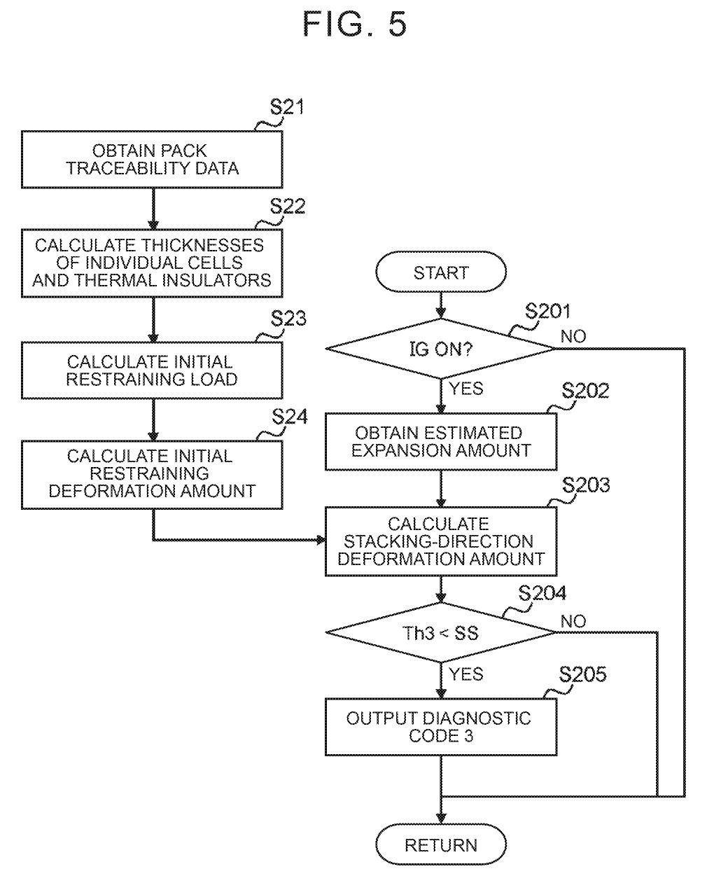

FIG. 5 is a flowchart illustrating a method for detecting an abnormality caused by deformation of the prismatic cells 10 in the stacking direction. One feature of the method illustrated in this flowchart is that the stacking-direction deformation amount is obtained through computation, rather than physically detecting the deformation of the prismatic cells 10 in the stacking direction using a sensor. This method can be executed by a computer.

The computation of the stacking-direction deformation amount is performed for a target prismatic cell among the prismatic cells 10 constituting the storage battery pack. In the present embodiment, the target prismatic cell is the prismatic cell located closest to the end plate 40 within the module, that is, the outermost prismatic cell. The outermost prismatic cell is the cell in which the shear-direction stress becomes the largest when expansion in the stacking direction occurs, that is, the cell in which shear detachment of the thermally conductive material 20 is most likely to occur. However, the target prismatic cell may be selected as desired. The target prismatic cell may be a single prismatic cell, two or more prismatic cells, or all of the prismatic cells.

In the flowchart shown in FIG. 5, the processes of steps S21 to S24 are preparatory processes that are executed once, for example, prior to shipment of the storage battery pack or prior to shipment of a BEV in which the storage battery pack is installed. In step S21, traceability data of the storage battery pack to be monitored for abnormality is obtained. The traceability data includes process data obtained during the manufacturing process of the storage battery pack. In step S22, the thicknesses of the individual prismatic cells and the thicknesses of individual thermal insulators each disposed between adjacent ones of the prismatic cells are calculated based on the traceability data. In step S23, the initial restraining load of the storage battery pack is calculated based on the traceability data. In step S24, the initial restraining deformation amount of the outermost prismatic cell, specifically, the initial value of the stacking-direction deformation amount, is calculated based on the thicknesses of the prismatic cells and the thermal insulators and the initial restraining load. The initial value of the stacking-direction deformation amount computed in step S24 is stored in the memory of the computer.

In the flowchart shown in FIG. 5, the processes of steps S201 to S205 are executed repeatedly each time the BEV is operated after shipment of the BEV in which the storage battery pack is installed. In step S201, it is determined whether the IG has been turned on. While the IG is off, the subsequent processes are skipped. When the IG is turned on, the processes from step S202 onward are executed.

In step S202, the estimated expansion amount of the outermost prismatic cell is obtained. There is no limitation on the method used to estimate the expansion amount. Assuming that the expansion amounts of all the prismatic cells are approximately equal, the average estimated expansion amount of the prismatic cells in the entire storage battery pack may be used as the estimated expansion amount of the outermost prismatic cell.

In step S203, the stacking-direction deformation amount of the outermost prismatic cell is calculated based on the initial value of the stacking-direction deformation amount calculated in step S24 and stored in the memory and the estimated expansion amount obtained in step S202. The estimated expansion amount is used to compute the amount of change in the stacking-direction deformation amount from the initial value. The relationship between the stacking-direction deformation amount and the expansion amount is defined by a physical model or a map.

In step S204, the stacking-direction deformation amount SS obtained in step S203 is compared with the shear detachment threshold Th3 to determine whether the stacking-direction deformation amount SS has increased to a level at which shear detachment of the thermally conductive material 20 may occur. When the stacking-direction deformation amount SS is less than or equal to the shear detachment threshold Th3, the subsequent processes are skipped. When the stacking-direction deformation amount SS is greater than the shear detachment threshold Th3, diagnostic code 3 is output in step S205. Diagnostic code 3 is an alert indicating a potential shear detachment of the thermally conductive material 20. The alert corresponding to diagnostic code 3 is herein referred to as "third alert."

### 4 Effects

In the method for detecting an abnormality caused by deformation of the bottom surfaces of the cases of the prismatic cells according to the present embodiment, the bottom surface deformation amount can be obtained through computation based on data. This allows an abnormality caused by deformation of the bottom surfaces 10b of the cases of the prismatic cells 10 to be detected without using a sensor that physically detects deformation. In the method for detecting an abnormality caused by deformation of the prismatic cells in the stacking direction according to the present embodiment, the stacking-direction deformation amount can be obtained through computation based on data. This allows an abnormality caused by deformation of the prismatic cells 10 in the stacking direction to be detected without using a sensor that physically detects deformation. By executing the above methods by a computer, it is possible to notify the user of a potential tensile detachment of the thermally conductive material 20 by the first alert, a potential short circuit by the second alert, and a potential shear detachment of the thermally conductive material 20 by the third alert.

The method for detecting an abnormality caused by deformation of the bottom surfaces of the cases of the prismatic cells according to the present embodiment, and the method for detecting an abnormality caused by deformation of the prismatic cells in the stacking direction according to the present embodiment, may be used in combination as described above, or either one of the methods may be used individually. However, combining the two methods that are based on different detection logic improves the accuracy in detecting detachment of the thermally conductive material 20.

What is claimed is:

1. A method for detecting an abnormality in a storage battery including a stack of a plurality of prismatic cells bonded to a base plate by a thermally conductive material, the method comprising:
calculating, based on process data obtained during a manufacturing process, an initial restraining deformation amount of a target prismatic cell in the stack;
calculating, based on the initial restraining deformation amount and usage history data, a deformation amount of a bottom surface of a case of the target prismatic cell; and
outputting a first alert in response to the deformation amount exceeding a predetermined first threshold.

2. The method according to claim 1, wherein the calculating the deformation amount based on the initial restraining deformation amount and the usage history data includes calculating an amount of change from an initial value of the deformation amount based on an expansion amount and an internal pressure of the target prismatic cell that are estimated from the usage history data, the initial value being the initial restraining deformation amount.

3. The method according to claim 1, wherein the target prismatic cell is a thinnest prismatic cell in the stack.

4. The method according to claim 1, wherein the first threshold is set to a value at which tensile detachment of the thermally conductive material from the bottom surface is expected to occur.

5. The method according to claim 1, further comprising outputting a second alert in response to the deformation amount exceeding a predetermined second threshold that is greater than the first threshold.

6. The method according to claim 5, wherein the second threshold is set to a value at which a short circuit is expected to occur due to contact between the case and an electrode assembly inside the case.
